(19) United States
(12) Patent Application Publication
(10) Pub. No.: US 2019/0163036 A1
(43) Pub. Date: May 30, 2019

(54) IMAGE PICKUP APPARATUS

(71) Applicant: Olympus Corporation, Tokyo (JP)

(72) Inventor: Ryuji KAMADA, Tokyo (JP)

(21) Appl. No.: 16/195,713

(22) Filed: Nov. 19, 2018

(30) Foreign Application Priority Data
Nov. 29, 2017 (JP) 2017-228930

(51) Int. Cl. G03B 17/55; H05K 7/20

(52) U.S. Cl. CPC G03B 17/55; H05K 7/2039

(57) ABSTRACT

An image pickup apparatus includes an electric board on which an electric element with heat generation is mounted, a first plate member including a first plane portion, in a position facing the electric element, and is parallel with the electric board, and a second plane portion folded perpendicularly to the first plane portion, a first heat conduction member disposed between the electric element and the first plate member in close contact, a rod-shaped heat pipe that includes an end portion for heat absorption and an end portion for heat dissipation, is fixed to a second surface, a second heat conduction member, and a second plate member disposed to face the second plane portion parallel with the second plane portion, and in close contact with the second heat conduction member to sandwich the second heat conduction member between the second plate member and the second plane portion.

### CROSS REFERENCE TO RELATED APPLICATION

This application claims the benefit of Japanese Application No. 2017-228930 filed in Japan on Nov. 29, 2017, the contents of which are incorporated herein by this reference.

### BACKGROUND OF THE INVENTION

### 1. Field of the Invention

The present invention relates to an image pickup apparatus including a structure that dissipates heat generated inside the apparatus by using a heat pipe.

### 2. Description of Related Art

In recent years, image pickup apparatuses which are electronic apparatuses each configured to convert an optical image of an object formed by an optical lens into an image signal by using an electric device such as an image pickup device and handle image data acquired thereby have been put to practical use in general and have been widely used.

The conventional electronic apparatus such as an image pickup apparatus of this kind is usually configured by including an electric board on which a plurality of electric elements are mounted, inside an apparatus casing.

In this case, it is well known that electric elements that generate heat as a result of the apparatus operating are present among the above described plurality of electric elements.

Heat that is generated from these electric elements becomes a cause of raising the temperature inside the casing of the electronic apparatus such as an image pickup apparatus.

Here, it is known that the temperature rise inside the casing becomes a factor that reduces the function of the electronic apparatus such as an image pickup apparatus. For example, when the temperature inside the casing rises in the image pickup apparatus or the like, there arises a problem that an unnecessary signal (noise) mixes into the image signal outputted from the image pickup device or the like. Further, there is also a possibility of deteriorating the performance of mounted components and the like on a board due to heat.

In addition to these problems, regarding the temperature rise inside the casing, a safety problem such as the possibility that an apparatus user gets burned, via an exterior member, can be also pointed out.

Therefore, devices for dissipating heat generated inside the casings of the electronic apparatuses such as an image pickup apparatus have been variously proposed conventionally by Japanese Patent Application Laid-Open Publication No. 2015-88888 and the like.

The image pickup apparatus disclosed by Japanese Patent Application Laid-Open Publication No. 2015-88888 described above includes a structure that cools the heat generated from electric elements with heat generation such as an image pickup device and IC by disposing a heat pipe inside the casing.

### SUMMARY OF THE INVENTION

In order to attain the above described object, an image pickup apparatus of one aspect of the present invention includes an electric element with heat generation, an electric board on which the electric element is mounted, a first plate member including a first plane portion that is a site placed parallel with the electric board, in a position facing the electric element, and parallel with the electric board, and a second plane portion that is disposed at an upper side of the first plane portion by being folded perpendicularly to the first plane portion, a first heat conduction member disposed between the electric element on the electric board and the first plate member to be in close contact with the electric element and the first plate member, a rod-shaped heat pipe that includes an end portion for heat absorption at one end and an end portion for heat dissipation at another end, is fixed to a second surface that is a back surface of a first surface that is in close contact with the first heat conduction member, of the first plate member, and has the end portion for heat absorption installed on the second surface in a vicinity of the electric element and has the end portion for heat dissipation installed on the second plane portion of the first plate member, a second heat conduction member, and a second plate member disposed on an upper portion of the image pickup apparatus to face the second plane portion parallel with the second plane portion, and in close contact with the second heat conduction member to sandwich the second heat conduction member between the second plate member and the second plane portion.

The advantage of the invention will further become apparent from the following detailed description.

### BRIEF DESCRIPTION OF THE DRAWINGS

FIG. 1 is an exterior perspective view mainly illustrating a rear side of an image pickup apparatus of one embodiment of the present invention;

FIG. 2 is an exploded perspective view of the image pickup apparatus of one embodiment of the present invention as seen from the rear side;

FIG. 3 is an exploded perspective view of the image pickup apparatus of one embodiment of the present invention as seen from a front side;

FIG. 4 is a plan view illustrating disposition of a heat pipe in the image pickup apparatus of one embodiment of the present invention; and

FIG. 5 is a plan view illustrating a modification of the disposition of the heat pipe of the image pickup apparatus of one embodiment of the present invention.

### DETAILED DESCRIPTION OF THE PREFERRED EMBODIMENT(S)

Hereinafter, the present invention will be described based on an illustrated embodiment. Respective drawings for use in the following explanation are schematic illustration, and in order to illustrate respective components in such sizes as to be recognizable on the drawings, dimensional relationships, scales and the like of the respective members may be illustrated by being caused to differ in each of the components. Accordingly, the present invention is not limited to only the illustrated modes, concerning quantities of the respective components, shapes of the respective components, ratios of dimensions of the respective components, relative positional relationships of the respective components and the like which are described in the respective drawings.

### One Embodiment

As an image pickup apparatus to which the present invention is applied, one embodiment of the present invention illustrates as an example an image pickup apparatus configured to photoelectrically convert an optical image formed by an optical lens, for example, by using an image pickup device, record an image signal obtained thereby in a storage medium as digital data expressing a still image and movie, and enable the still image and movie to be reproduced and displayed on a display device based on an image based on the image signal, or digital image data or the like recorded in the storage medium.

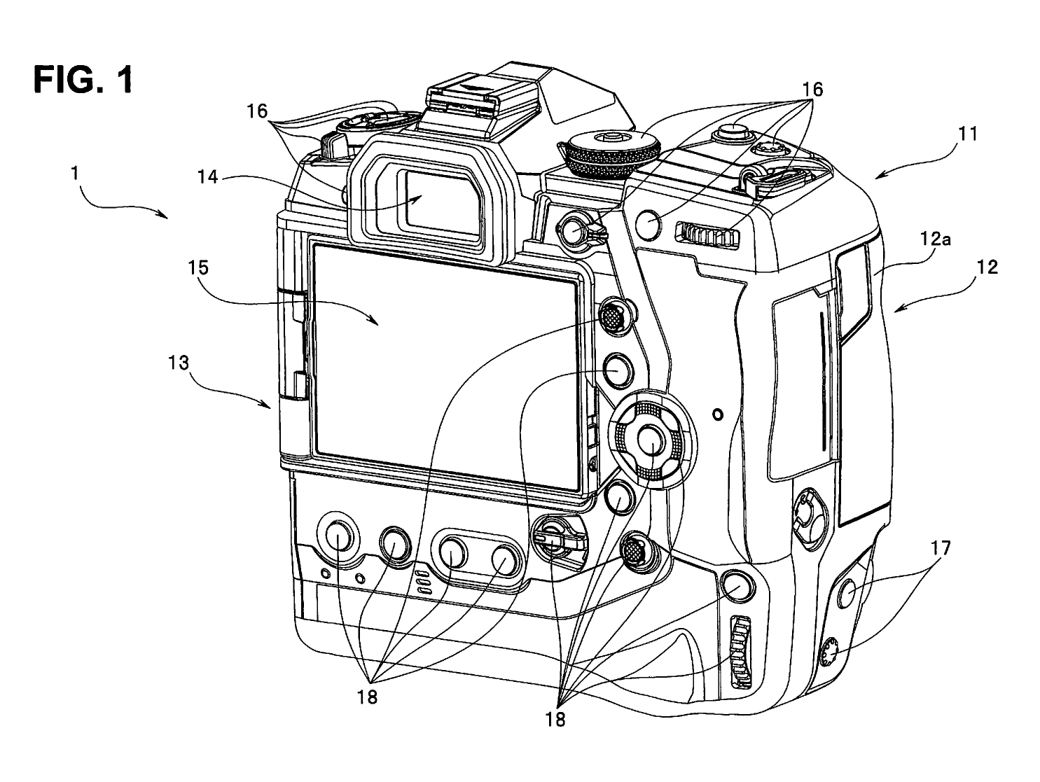

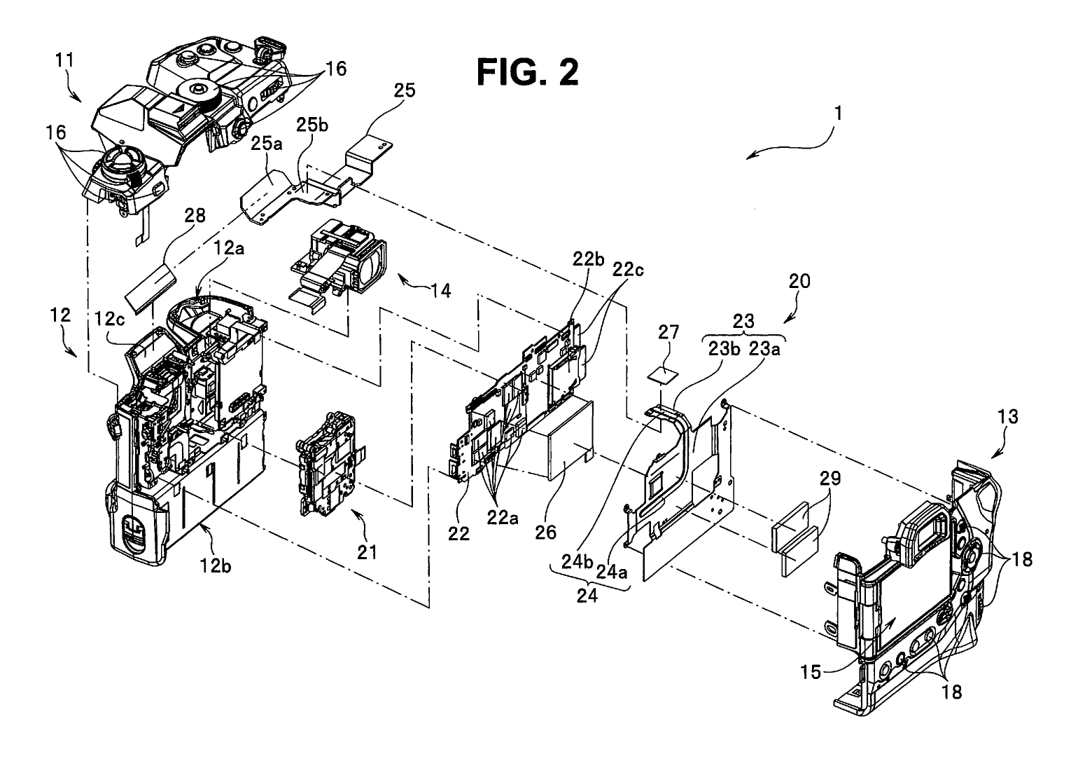

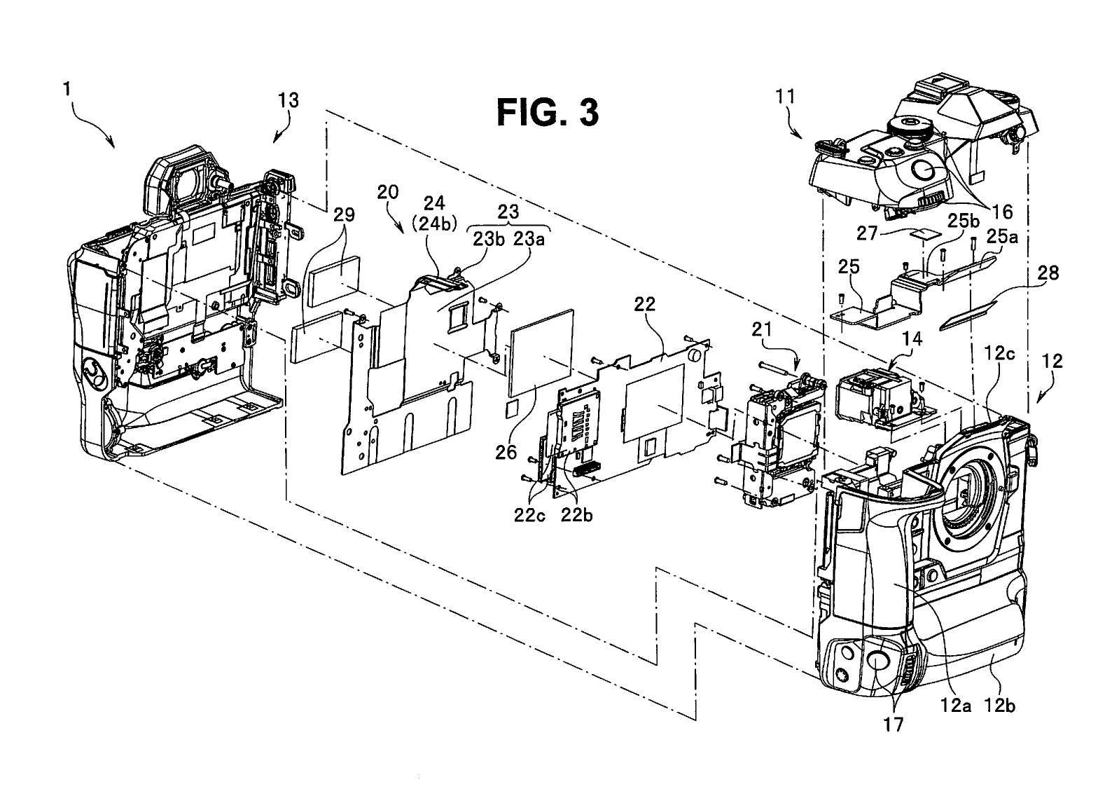

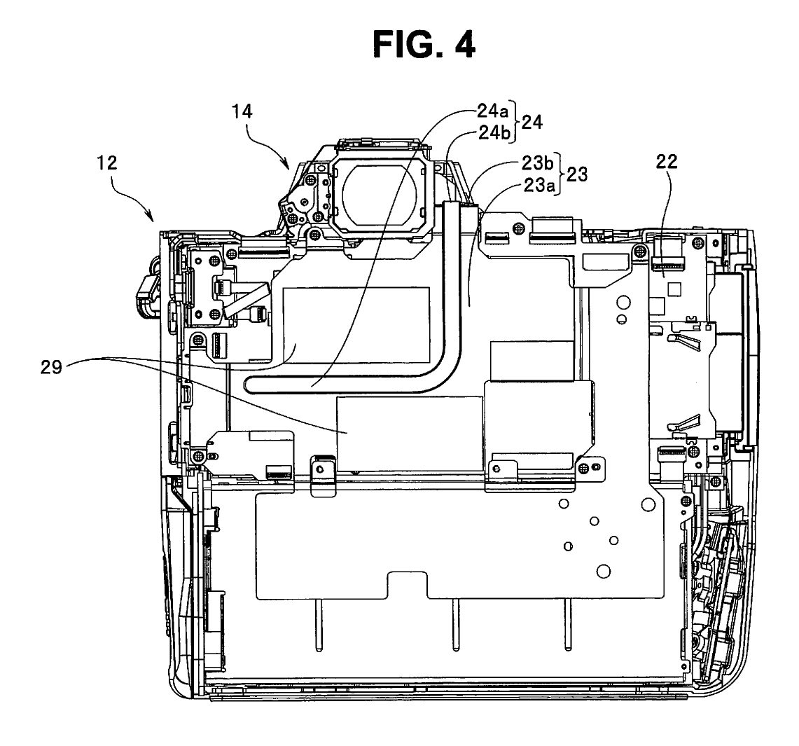

FIG. 1 is an exterior perspective view mainly illustrating a rear side of the image pickup apparatus of one embodiment of the present invention. FIGS. 2 and 3 are exploded perspective views of the image pickup apparatus of one embodiment of the present invention. Of FIGS. 2 and 3, FIG. 2 is an exploded perspective view of the image pickup apparatus as seen from the rear side of the image pickup apparatus. FIG. 3 is an exploded perspective view of the image pickup apparatus of one embodiment of the present invention as seen from a front side of the image pickup apparatus. FIG. 4 is a view illustrating disposition of a heat pipe in the image pickup apparatus of one embodiment of the present invention. FIG. 4 is a plan view of a state where a rear cover unit and an upper cover unit of the image pickup apparatus are detached as seen from the rear side.

First, a configuration of the image pickup apparatus of the present embodiment will be described hereinafter with use of FIGS. 1 to 4.

As illustrated in FIGS. 1 to 3, an image pickup apparatus 1 of the present embodiment is mainly configured of a plurality of cover units (11, 12, 13) configuring an exterior casing, configuration units (14, 15, 20, 21, 22) respectively placed in predetermined positions inside and on an outer surface of the exterior casing, pluralities of operation members (16, 17, 18) and the like.

As a plurality of cover units configuring the exterior casing, there are an upper cover unit 11, a front cover unit 12 and a rear cover unit 13.

The upper cover unit 11 is an exterior member that is disposed on a top surface portion of the image pickup apparatus 1, and is disposed to mainly cover a top surface of the image pickup apparatus 1.

The front cover unit 12 is a first exterior member that is disposed on a front surface portion of the image pickup apparatus 1, and is disposed to cover mainly a front surface of the image pickup apparatus 1.

In the front cover unit 12, a grip portion 12a and a battery housing portion 12b are formed.

The grip portion 12a is formed to protrude forward on a right-hand side facing a rear surface of the image pickup apparatus 1. The grip portion 12a is a site that is grasped with a right hand when a user holds the image pickup apparatus 1 in a normal state when the user uses the image pickup apparatus 1. Inside the grip portion 12a, a configuration unit and the like that realize, for example, a radio communication function are housed.

The battery housing portion 12b is formed on a bottom surface of the image pickup apparatus 1. Inside the battery housing portion 12b, for example, a plurality of batteries are housed. Further, the battery housing portion 12b is a site that is grasped by a right hand when the user holds the image pickup apparatus 1 so that an image pickup screen is vertically oriented when the user uses the image pickup apparatus 1. Accordingly, the battery housing portion 12b also functions as a grip portion at a time of vertical position shooting.

The rear cover unit 13 is a second exterior member that is disposed at a rear surface portion of the image pickup apparatus 1 and is disposed to mainly cover the rear surface and the bottom surface of the image pickup apparatus 1.

The upper cover unit 11, the front cover unit 12 and the rear cover unit 13 are each formed by using a metal material having favorable heat conductivity such as a magnesium die-cast alloy.

The exterior casing of the present image pickup apparatus 1 is formed by being configured by combining the upper cover unit 11, the front cover unit 12 and the rear cover unit 13.

The pluralities of operation members (16, 17, 18) are respectively placed in predetermined positions, on respective outer surfaces of the upper cover unit 11, the front cover unit 12 and the rear cover unit 13.

Here, a plurality of operation members provided at the upper cover unit 11 are denoted by reference sign 16. Further, a plurality of operation members provided at the front cover unit 12 are denoted by reference sign 17. A plurality of operation members provided at the rear cover unit 13 are denoted by reference sign 18.

The pluralities of operation members (16, 17, 18) are members for a user to operate the image pickup apparatus 1. Therefore, as for the pluralities of operation members (16, 17, 18), there are operation members of various modes, such as a push button type, a rotary-dial type, a lever type, a joystick type, and a slide type. Note that the pluralities of operation members (16, 17, 18) are portions that do not directly relate to the present invention, so that detailed explanation of individual functions and the like will be omitted.

As configuration units that are respectively placed at predetermined positions inside and on the outer surface of the exterior casing, the finder unit 14, the display unit 15, the cooling unit 20, the image pickup unit 21, the main board unit 22 and the like are used.

The finder unit 14 is a unit configured by including a compact display apparatus configured to display an image or the like by receiving an image signal formed by the image pickup device, and display various kinds of setting information, and the like. The finder unit 14 is fixed by screws or the like in a substantially central portion on the top surface of the front cover unit 12. The finder unit 14 is entirely covered with the upper cover unit 11.

The display unit 15 is a unit having a similar function to the function of the above described finder unit 14, and configured by including a display apparatus or the like which is slightly larger than the above described finder unit 14. The display unit 15 is placed on an outer surface on the rear side of the rear cover unit 13 (not illustrated in FIG. 3). As the display apparatus applied to the display unit 15, a display apparatus including a touch panel is adopted. Accordingly, the display unit 15 also functions as an operation member by the touch panel.

The image pickup unit 21 is a unit configured by including an image stabilization mechanism (image stabilization system), a sensor surface dust removing mechanism (dust reduction system) and the like in addition to the image pickup device, a drive circuit of the image pickup device and various signal processing circuits and the like. The image pickup unit 21 is placed in a substantially central portion of the front cover unit 12 inside the present image pickup apparatus 1 (not illustrated in FIG. 1). Here, the image pickup unit 21 is fixed to the front cover unit 12 by screws or the like.

The main board unit 22 is an electric board (not illustrated in FIG. 1) on which a plurality of electric elements are mounted. The main board unit 22 is placed in a rear part of the above described image pickup unit 21 inside the present image pickup apparatus 1 (not illustrated in FIG. 1). Here, the main board unit 22 is fixed to the front cover unit 12 by screws or the like.

On the main board unit 22, a plurality of electric elements 22a with heat generation, a card slot portion 22b to and from which a storage medium (memory card) 22c is attachable and detachable and the like are mounted.

Here, as the plurality of electric elements 22a with heat generation, a plurality of ASICs (application specific integrated circuit; integrated circuit for specific application) for performing high-speed image processing, various kinds of control processing and arithmetic operation processing, a plurality of power supply ICs (integrated circuit), a plurality of memory ICs including a buffer memory and the like are used.

Note that respective basic configurations of the finder unit 14, the display unit 15, the image pickup unit 21 and the main board unit 22 are substantially similar to the basic configurations of the units applied in the conventional image pickup apparatus. Accordingly, detailed explanation of the configuration units will be omitted.

The cooling unit 20 is a configuration unit that is provided to dissipate the generated heat from the plurality of electric elements 22a with heat generation which are mounted on the above described electric board 22, to outside. The cooling unit 20 is placed at a rear part of the main board unit 22 (not illustrated in FIG. 1).

The cooling unit 20 is configured of a first plate member 23, a heat pipe 24, a second plate member 25, and a plurality of heat conduction members (26, 27, 28, 29) and the like.

Here, the above described plurality of heat conduction members include a first heat conduction member 26, a second heat conduction member 27, a third heat conduction member 28 and a fourth heat conduction member 29. The plurality of heat conduction members all include, for example, heat conductivity, have elasticity, and are each formed into a sheet shape, and existing products which are conventionally put to practical use in general as the heat conduction members can be applied. Details of disposition of the respective members and the like will be described later.

The first plate member 23 is a plate-shaped member that is placed in a rear part of the main board unit 22 in the exterior casing of the image pickup apparatus 1. The first plate member 23 is formed by using a metal material having favorable heat conductivity such as aluminum.

Further, the first plate member 23 is formed by applying folding, boring, cutting and the like to a plate-shaped member, for example. Therefore, the first plate member 23 is formed by having a first plane portion 23a and a second plane portion 23b.

Here, the first plane portion 23a in the first plate member 23 is a site that is placed at a position facing the plurality of electric elements 22a on the main board unit 22, and is formed of a plane that is parallel with the main board unit 22.

Further, the second plane portion 23b in the first plate member 23 is a site formed by folding a part of an upper part of the first plane portion 23a substantially perpendicularly to the first plane portion 23a. In the second plane portion 23b, a folded tip end extends forward and is disposed above the front cover unit 12. In this case, (a fourth plane portion 25b) of the second plate member 25 and the second heat conduction member 27 are sandwiched between the second plane portion 23b and the top surface of the front cover unit 12, as will be described later.

The first heat conduction member 26 is disposed by being sandwiched between the plurality of electric elements 22a on the main board unit 22 and the first plane portion 23a of the first plate member 23. In this case, in the first heat conduction member 26, one surface is in close contact with outer surfaces of the above described plurality of electric elements 22a, and the other surface is in close contact with a front surface of the first plane portion 23a of the first plate member 23.

Note that, in the first plane portion 23a of the first plate member 23, the surface with which the first heat conduction member 26 is in close contact is referred to as a first surface. Further, a back surface of the first surface is referred to as a second surface. On the second surface, (a heat absorption portion 24a of) the heat pipe 24 is installed, as will be described later.

The heat pipe 24 is a component formed into a rod shape. The heat pipe 24 is formed by including the heat absorption portion 24a which is an end portion for heat absorption at one end, and a heat dissipation portion 24b that is an end portion 24b for heat dissipation at the other end. The heat pipe 24 is fixed to the second surface of the first plate member 23 by means such as soldering.

At this time, the heat absorption portion 24a (end portion for heat absorption) of the heat pipe 24 is installed on the second surface (that is, a vicinity of the plurality of electric elements 22a) of the first plate member 23. Here, the heat absorption portion 24a of the heat pipe 24 linearly extends from an upper side of the first plate member 23 toward a lower side in a perpendicular direction along the first plane portion 23a of the first plate member 23, thereafter bends in a predetermined position, and extends in a horizontal direction toward a site facing a region where the plurality of electric elements 22a are disposed, as illustrated in FIG. 4 and the like.

In other words, the heat absorption portion 24a of the heat pipe 24 is installed by being formed into an inverted L shape as seen from the rear side (that is, from a position facing the second surface of the first plane portion 23a of the first plate member 23), on the second surface of the first plane portion 23a of the first plate member 23 (refer to FIG. 4).

Further, the second surface of the first plane portion 23a of the first plate member 23 is disposed to face an inner surface of the rear cover unit 13 (second exterior member). The fourth heat conduction member 29 is disposed by being sandwiched between the second surface of the first plane portion 23a and the rear cover unit 13 in close contact with the second surface and the rear cover unit 13. Here, for example, two of the fourth heat conduction members 29 are disposed in the vicinity of the heat pipe 24 in the second surface of the first plane portion 23a of the first plate member 23, as illustrated in FIG. 4.

The heat dissipation portion 24b (end portion for heat dissipation) of the heat pipe 24 is installed on the second plane portion 23b (that is, an upper side of the first plate member 23) of the first plate member 23.

Note that as for the heat pipe itself a substantially similar heat pipe to heat pipes conventionally put to practical use in general is assumed to be applied, and a detailed configuration of the heat pipe will be omitted.

The second plate member 25 is a plate-shaped member placed on a top surface portion of the front cover unit 12 in the exterior casing of the image pickup apparatus 1. The second plate member 25 is formed by using a metal material having high heat conductivity such as aluminum, similarly to the aforementioned first plate member 23.

Further, the second plate member 25 is formed by applying folding, boring, cutting and the like to a plate-shaped member, for example, similarly to the aforementioned first plate member 23. Therefore, the second plate member 25 is formed by having a third plane portion 25a and the fourth plane portion 25b.

Here, the fourth plane portion 25b in the second plate member 25 is formed of a plane that is formed to face the second plane portion 23b of the first plate member 23 parallel to the second plane portion 23b. That is, the second plane portion 23b of the first plate member 23 is disposed on a top surface side of the fourth plane portion 25b. The second heat conduction member 27 is disposed in a form sandwiched between the fourth plane portion 25b and the second plane portion 23b of the first plate member 23 in close contact with the fourth plane portion 25b and the second plane portion 23b.

Further, the third plane portion 25a in the second plate member 25 is a site formed by being folded upward by a predetermined angle from the above described fourth plane portion 25b. The third plane portion 25a is placed in a position facing one plane portion 12c of the front cover unit 12 (first exterior member). The third heat conduction member 28 is disposed in a form sandwiched between the third plane portion 25a and the one plane portion 12c of the front cover unit 12 in close contact with the third plane portion 25a and the one plane portion 12c.

The above described plurality of heat conduction members are respectively disposed as follows.

The first heat conduction member 26 is disposed by being sandwiched between the plurality of electric elements 22a on the main board unit 22 and the first plane portion 23a of the first plate member 23.

The second heat conduction member 27 is disposed by being sandwiched between the fourth plane portion 25b of the second plate member 25 and the second plane portion 23b of the first plate member 23 in close contact with the fourth plane portion 25b and the second plane portion 23b.

The third heat conduction member 28 is disposed by being sandwiched between the third plane portion 25a of the second plate member 25 and the one plane portion 12c of the front cover unit 12 in close contact with the third plane portion 25a and the one plane portion 12c.

The fourth heat conduction member 29 is disposed by being sandwiched between the second surface of the first plane portion 23a and the rear cover unit 13 in close contact with the second surface and the rear cover unit 13.

Note that there exist other configuration units placed inside the exterior casing than the aforementioned configuration units, but these configuration units are parts that are not directly related to the present invention, and therefore explanation of the configuration units will be omitted.

An operation of the cooling unit 20 in the image pickup apparatus 1 of the present embodiment configured in this way will be described hereinafter.

With use of the image pickup apparatus 1 (image pickup operation, for example), the plurality of electric elements 22a on the main board unit 22 generate heat. Then, the heat is firstly conducted to the first heat conduction member 26 which is in close contact with the plurality of electric elements 22a.

The first heat conduction member 26 is in close contact with the first surface of the first plane portion 23a of the first plate member 23. Accordingly, the heat is conducted to the first plane portion 23a of the first plate member 23 from the first heat conduction member 26. Since the first plate member 23 is formed of a metal material having thermal conductivity, the heat diffuses onto the first plate member 23. At this time, the heat is conducted to the second surface from the first surface.

On the second surface of the first plane portion 23a of the first plate member 23, the heat absorption portion 24a of the heat pipe 24 is installed. Accordingly, the conducted heat on the first plate member 23 is absorbed by the heat absorption portion 24a of the heat pipe 24, and thereafter is conducted to the heat dissipation portion 24b of the heat pipe 24.

The heat dissipation portion 24b of the heat pipe 24 is installed on the second plane portion 23b of the first plate member 23. The second plane portion 23b is in close contact with the fourth plane portion 25b of the second plate member 25 via the second heat conduction member 27. Accordingly, the heat that is dissipated from the heat dissipation portion 24b of the heat pipe 24 is conducted to the second plate member 25. Subsequently, the heat diffuses onto the second plate member 25.

Then, the heat is conducted to the one plane portion 12c of the front cover unit 12 via the third heat conduction member 28 from the third plane portion 25a of the second plate member 25. Since the front cover unit 12 is formed of a metal material having heat conductivity, the heat diffuses onto the front cover unit 12. The front cover unit 12 is the exterior member of the image pickup apparatus 1, and an outer surface of the front cover unit 12 is in contact with an outside in a wide area. Accordingly, the heat conducted to the front cover unit 12 is efficiently dissipated to the outside.

A part of the heat that is conducted from the plurality of electric elements 22a to the first plate member 23 via the first heat conduction member 26 is also conducted to the rear cover unit 13 via the fourth heat conduction member 29. The rear cover unit 13 is also the exterior member of the image pickup apparatus 1, and the outer surface of the rear cover unit 13 is in contact with the outside in a wide area. Accordingly, the heat that is conducted to the rear cover unit 13 is also efficiently dissipated to the outside.

As described above, according to the above described one embodiment, the cooling unit 20 configured by using the heat pipe 24 is provided in the vicinity of the main board unit 22 on which the plurality of electric elements 22a with heat generation are mounted, and while the heat absorption portion 24a of the heat pipe 24 is installed in the vicinity of the plurality of electric elements 22a, the heat dissipation portion 24b of the heat pipe 24 is disposed on the top surface side of the image pickup apparatus 1. Further, on the path through which the heat generated from the plurality of electric elements 22a is conducted, the heat conduction members (26, 27, 28, 29) having thermal conductivity and the plate members (23, 25) formed from the materials having thermal conductivity are disposed. The heat generated inside the apparatus (heat generated in the plurality of electric elements 22a) is configured to be finally conducted to the exterior members (12, 13) having thermal conductivity via the above described heat conduction path, and is dissipated to outside.

According to the configuration like this, the heat generated from the plurality of electric elements 22a and the like (heat generated inside the apparatus) can be efficiently dissipated to outside. Accordingly, the function of the image pickup apparatus 1 can be prevented from being inhibited due to the heat generation.

Note that as for disposition of the heat pipe 24 an installation shape can be devised arbitrarily by considering the disposition configuration of the internal configuration units of the image pickup apparatus 1, and is not limited to the mode illustrated in the aforementioned one embodiment.

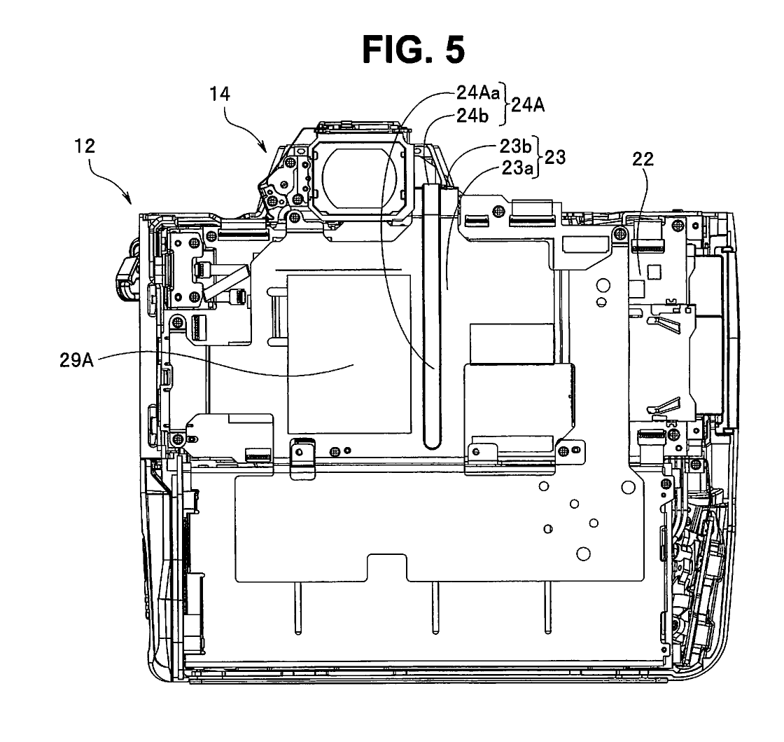

For example, FIG. 5 is a view illustrating a modification about the disposition of the heat pipe. FIG. 5 is also a plan view of a state where a rear cover unit and an upper cover unit of an image pickup apparatus are detached as seen from a rear side, similarly to FIG. 4.

The modification illustrated in FIG. 5 differs in only shape of a heat pipe 24A. In the heat pipe 24A of the modification, a shape of a portion (heat absorption portion 24Aa) that is installed on the second surface of the first plane portion 23a of the first plate member 23 differs.

That is, in the present modification, the heat absorption portion 24Aa of the heat pipe 24A is in a shape that only extends linearly from an upper side of the first plate member 23 toward a lower side in a perpendicular direction along the first plane portion 23a of the first plate member 23 as illustrated in FIG. 5.

Further, as the heat pipe 24A is formed into the shape like this, the present modification is configured by placing only a single fourth heat conduction member 29A. The other configurations are quite the same as the configurations of the aforementioned one embodiment.

According to the modification of the one embodiment of the present invention configured in this way, a similar effect to the effect of the aforementioned one embodiment can be obtained.

In general, as for a heat dissipating operation which is performed by using a heat pipe, it is considered that the heat dissipation portion is desirably disposed on an upper side with respect to the heat absorption portion. Further, it is considered that a more efficient heat dissipation effect can be obtained by installing the heat pipe linearly in the vertical direction.

Consequently, according to the configuration of the present modification, a more excellent and efficient heat dissipation effect can be expected, with respect to the configuration of the heat pipe illustrated in FIGS. 2 to 4 in the aforementioned one embodiment.

On the other hand, the configuration of the aforementioned one embodiment (in particular, refer to FIG. 4) can obtain a further effect of being able to perform an efficient heat absorption operation and heat dissipation operation in a case where a plurality of electric elements with large heat generation are present, for example.

That is, when the configuration (refer to FIG. 4, in particular) of the aforementioned one embodiment is adopted, the heat absorption portion of the heat pipe can be easily disposed in a vicinity of the electric elements with large heat generation. Accordingly, by adopting the configuration, some degrees of freedom can be given when a plurality of electric elements with large heat generation are disposed on the board.

The present invention is not limited to the aforementioned embodiment, and it is needless to say that various modifications and applications can be carried out within the range without departing from the gist of the invention. Further, the above described embodiment includes the inventions at various stages, and various inventions can be extracted by arbitrary combination in the plurality of components which are disclosed. For example, even when some components are deleted from all the components shown in the above described one embodiment, if the problem to be solved by the invention can be solved, and the effect of the invention can be obtained, the configuration from which the components are deleted can be extracted as the invention. Further, the components across different embodiments may be arbitrarily combined. The invention is not restricted by the specific embodiment of the invention except that the invention is limited by the accompanying claims.

The present invention is not limited by only an image pickup apparatus, but can be widely applied to electronic apparatuses in other modes having heat generation sources, and electronic apparatuses with various image pickup functions, such as a digital camera, a video camera, a movie camera, a cellular phone, a smartphone, an electronic notepad, an electronic dictionary, a personal digital assistant, a personal computer, a tablet-type device, game equipment, a television receiver, a watch, a navigation apparatus using a GPS (global positioning system).

Further, the present invention can be also applied similarly to electronic apparatuses each having a function of acquiring an image by using an image pickup device and displaying the acquired image by using a display apparatus, observing apparatuses such as a telescope, a binocular, a monocle, and a microscope.

Further, the present invention can be also applied similarly to image pickup apparatuses such as a surveillance camera and an onboard camera besides industrial or medical observation apparatuses such as an endoscope and a microscope and the like.

In addition to the above, the present invention can be also applied similarly to a projection type image display apparatus that enlarges and projects an image by using a transmissive liquid crystal display apparatus, for example, and the like.

What is claimed is:

1. An image pickup apparatus comprising:
an electric element with heat generation;
an electric board on which the electric element is mounted;
a first plate member including a first plane portion that is a site placed parallel with the electric board, in a position facing the electric element, and parallel with the electric board, and a second plane portion that is disposed at an upper side of the first plane portion by being folded perpendicularly to the first plane portion;
a first heat conduction member disposed between the electric element on the electric board and the first plate member to be in close contact with the electric element and the first plate member;
a rod-shaped heat pipe that includes an end portion for heat absorption at one end and an end portion for heat dissipation at another end, is fixed to a second surface that is a back surface of a first surface that is in close contact with the first heat conduction member, of the first plate member, and has the end portion for heat absorption installed on the second surface in a vicinity of the electric element and has the end portion for heat dissipation installed on the second plane portion of the first plate member;
a second heat conduction member; and
a second plate member disposed on an upper portion of the image pickup apparatus to face the second plane portion parallel with the second plane portion, and in close contact with the second heat conduction member to sandwich the second heat conduction member between the second plate member and the second plane portion.

2. The image pickup apparatus according to claim 1, further comprising:
a third heat conduction member; and
a first exterior member formed of a metal and disposed at a front surface side of the image pickup apparatus,
wherein a folded third plane portion is further formed in the second plate member, and the third heat conduction member is sandwiched between the third plane portion and the first exterior member in close contact with the third heat conduction member.

3. The image pickup apparatus according to claim 1, further comprising:
a fourth heat conduction member; and
a second exterior member formed of a metal and disposed on a rear surface side of the image pickup apparatus,
wherein the fourth heat conduction member is sandwiched between the first plane portion and the second exterior member in close contact with the fourth heat conduction member.
